(19) United States
(12) Patent Application Publication
(10) Pub. No.: US 2023/0137992 A1
(43) Pub. Date: May 4, 2023

(54) METHOD FOR IMPROVING THE SURFACE ROUGHNESS OF A SILICON-ON-INSULATOR WAFER

(71) Applicant: SHANGHAI INSTITUTE OF MICROSYSTEM AND INFORMATION TECHNOLOGY CHINESE ACADEMY OF SCIENCES, Shanghai (CN)

(72) Inventors: Xing Wei, Shanghai (CN); Rong Wang Dai, Shanghai (CN); Zi Wen Wang, Shanghai (CN); Zhong Ying Xue, Shanghai (CN); Meng Chen, Shanghai (CN); Hong Tao Xu, Shanghai (CN); Ming Hao Li, Shanghai (CN)

(73) Assignee: SHANGHAI INSTITUTE OF MICROSYSTEM AND INFORMATION TECHNOLOGY CHINESE ACADEMY OF SCIENCES, Shanghai (CN)

(21) Appl. No.: 17/585,557

(22) Filed: Jan. 27, 2022

(30) Foreign Application Priority Data
Oct. 29, 2021 (CN) 202111269452.6

(51) Int. Cl. H01L 21/324

(52) U.S. Cl. CPC H01L 21/324

(57) ABSTRACT

The present disclosure relates to a method for improving the surface roughness of a SOI wafer. By controlling the gas composition at each stage of the rapid thermal treatment process and corresponding heating and annealing processes, the final wafer is enabled to have a surface roughness of less than 5Å and has good application prospects.

### CROSS-REFERENCE TO RELATED APPLICATION

This application claims the priority benefit of China application serial no. 202111269452.6, filed on Oct. 29, 2021. The entirety of the above-mentioned patent application is hereby incorporated by reference herein and made a part of this specification.

### BACKGROUND

### Technical Field

The present disclosure belongs to the field of silicon-on-insulators, and particularly relates to a method for improving the surface roughness of a silicon-on-insulator wafer.

### Description of Related Art

Surface roughness of the top silicon layer of a silicon-on-insulator (SOI) wafer needs to be well controlled as it affects the characteristics of a subsequent device. Currently, there are two main methods for improving the surface roughness of SOI. One involves thermal annealing under a hydrogen or argon atmosphere (which can be divided into rapid thermal annealing and long-term thermal annealing) to firstly remove the natural oxidized layer and other organic pollutants from the surface of the top silicon layer, and then gradually form a relatively smooth surface topography through migration and reconstruction of silicon surface atoms. The other involves selective etching of the surface of the top silicon layer with hydrogen chloride to obtain a smooth surface. Etching with hydrogen chloride requires removing a part of the silicon from the top layer, which makes it not easy to ensure homogeneity. In contrast, it is quite easy to control process parameters of thermal annealing, while not affecting homogeneity of thickness.

U.S. Pat. No. 7,883,628B2 provides a method for reducing the surface roughness of a semiconductor wafer by rapid thermal annealing. Specifically, in the early stage of heating-up (below 850° C.), the reaction chamber atmosphere for rapid thermal annealing is a mixture of hydrogen and argon. Then, this atmosphere is switched to a pure argon atmosphere, and the temperature is further increased to the target temperature, followed by annealing and maintaining this pure argon atmosphere until the end of cooling. However, as the effective reaction temperature for hydrogen to reduce silicon oxide should be greater than 1000° C., the temperature for reaction in the mixture of hydrogen and argon is too low. As a result, the natural oxidized layer on the surface cannot be completely removed. On the other hand, an excessively high concentration of hydrogen in the hydrogen-argon mixture will etch the surface to some extent, thereby rendering the final surface roughness of the wafer fail to reach the target roughness.

Therefore, it is necessary to look for a new method for improving the surface roughness of a wafer.

### SUMMARY

The present disclosure provides a method for improving a surface roughness of SOI wafers. By controlling the gas composition at each stage of the rapid thermal treatment process and corresponding heating and annealing processes, the final wafer is enabled to have a surface roughness of less than 5Å and has good application prospects.

The present disclosure provides a method for improving the surface roughness of a SOI wafer, including: loading a wafer with a SOI structure having an initial surface roughness of greater than 10Å into a rapid thermal treatment reaction chamber at the temperature of 100° C. to 400° C. in an atmosphere of pure Ar, and maintaining this for 10 s to 120 s; then switching the atmosphere to a mixed atmosphere of Ar+n % H₂ and starting to heat up, wherein n is less than 10 (preferably less than 3); increasing the temperature to a range of 1150° C. to 1300° C. (preferably from 1200° C. to 1250° C.) followed by annealing for 10 s to 120 s (preferably from 20 s to 50 s); maintaining the atmosphere to be pure Ar after the annealing process is completed, and taking out the wafer when the temperature is decreased to below 600° C.

The pressure of the reaction chamber is a normal pressure or low pressure in the range of 1 mbar to 1010 mbar.

The heating rate is 30° C/s to 100° C/s, preferably 50° C/s to 70° C/s.

After the temperature is increased to a range of 1150° C. to 1300° C., the mixed atmosphere of Ar+n % H₂ in the heating-up stage is maintained, or switched to a pure Ar atmosphere.

The cooling rate is 30° C/s to 100° C/s, preferably 50° C/s to 70° C/s.

By controlling the gas composition at each stage of the rapid thermal treatment process and corresponding heating and annealing processes, the final wafer is enabled to have a surface roughness of less than 5Å and has good application prospects.

### BRIEF DESCRIPTION OF THE DRAWINGS

FIG. 1 shows a schematic cross-sectional view of a SOI structure;

FIG. 2 shows the temperature curve and atmosphere of the process of the present disclosure;

FIG. 3 shows a non-contact scanning image of a SOI wafer surface AFM 10 μm ×10 μm before and after annealing in Example 1;

FIG. 4 shows a non-contact scanning image of a SOI wafer surface AFM 10 μm ×10 μm before and after annealing in Example 2.

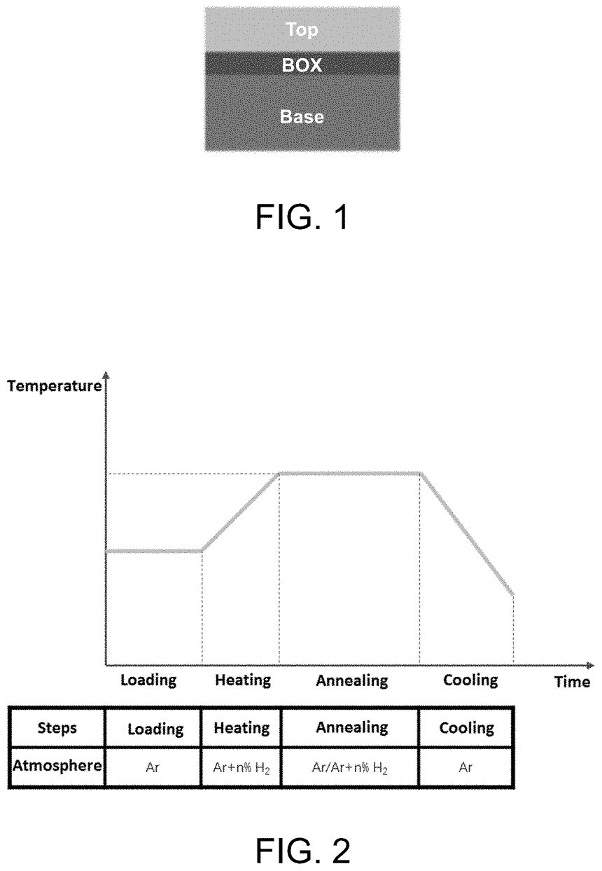

### DESCRIPTION OF THE EMBODIMENTS

The present disclosure is further described below in conjunction with specific Examples. It should be appreciated that these Examples are only used to illustrate the present disclosure rather than to limit the scope of the present disclosure. The method for improving roughness of the present disclosure is applicable to all semiconductor wafers. In addition, it should be appreciated that, upon reading the content taught by the present disclosure, a person skilled in the art can make various changes or modifications to the present disclosure, and these equivalents also fall within the scope defined by the appended claims of the present application.

### Example 1

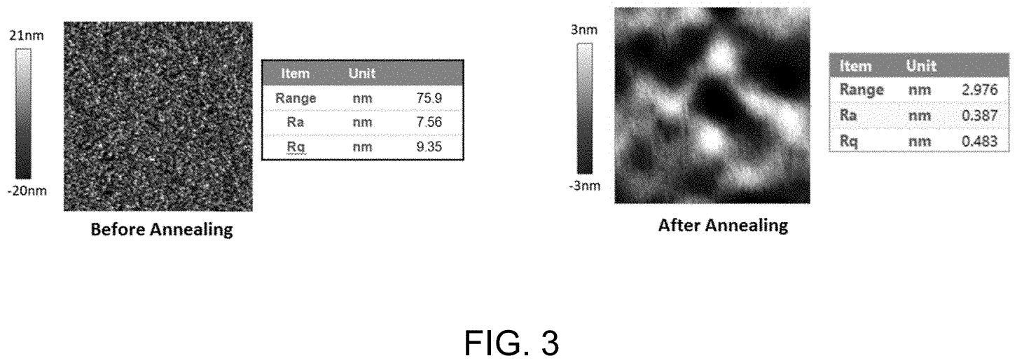

The left figure of FIG. 3 is a non-contact scanning image of a SOI wafer surface AFM 10 μm ×10 μm obtained by the Smart-cut process. The wafer has a surface roughness of 93.5Å.

The above wafer was loaded into a rapid thermal treatment reaction chamber at the loading temperature of 200° C., with the chamber pressure being atmospheric pressure of 1010 mbar, and the atmosphere being pure Ar. This was maintained for 30 s. Then, the atmosphere was switched to a mixed atmosphere of Ar+2.5% H₂, and the temperature was increased at the heating rate of 70° C/s. When the temperature reached the target temperature, the atmosphere was switched to pure Ar followed by the annealing process at the temperature of 1250° C. for 30 s. The atmospheric environment remained pure Ar after the annealing process was completed, and the temperature was decreased to room temperature at the cooling rate of 50° C/s before the wafer was taken out. The right figure of FIG. 3 is a non-contact scanning image of AFM 10 μm ×10 μm after annealing. The wafer has a surface roughness of 4.8Å after annealing.

### Example 2

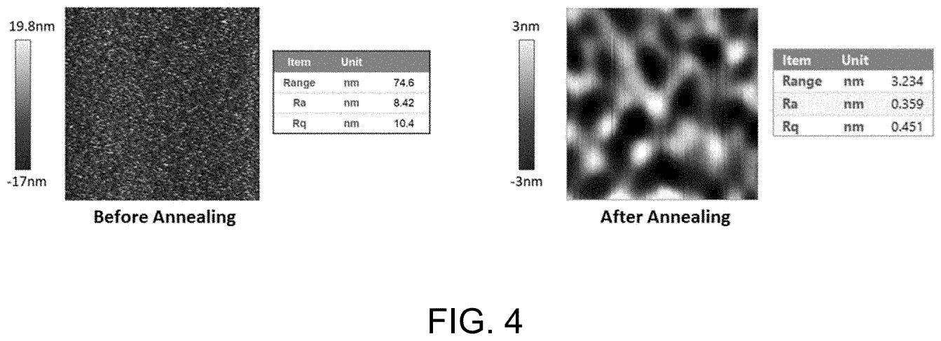

The left figure of FIG. 4 is a non-contact scanning image of a SOI wafer surface AFM 10 μm ×10 μm obtained by the Smart-cut process. The wafer has a surface roughness of 104Å.

The above wafer was loaded into a rapid thermal treatment reaction chamber at the loading temperature of 200° C., with the chamber pressure being atmospheric pressure of 1010 mbar, and the atmosphere being pure Ar. This was maintained for 30 s. Then, the atmosphere was switched to a mixed atmosphere of Ar+2.5% H₂, and the temperature was increased at the heating rate of 70° C/s and the H₂/Ar mixed atmosphere was remained. When the temperature reached the target temperature, an annealing process was initiated, the temperature was 1250° C. and the annealing process was continued for 30 s, then the atmosphere was switched to pure Ar after the annealing process was completed. The temperature was decreased to room temperature at the cooling rate of 50° C/s before the wafer was taken out. The right figure of FIG. 4 is a non-contact scanning image of AFM 10 μm ×10 μm after annealing. The wafer has a surface roughness of 4.5Å after annealing.

What is claimed is:

1. A method for improving the surface roughness of a SOI wafer, comprising:
loading a wafer with a SOI structure into a rapid thermal treatment reaction chamber at the temperature of 100° C. to 400° C. in an atmosphere of pure Ar, and maintaining this for 10 s to 120 s; then switching the atmosphere to a mixed atmosphere of Ar+n % H₂ and starting to heat up, wherein n is less than 10; increasing the temperature to a range of 1150° C. to 1300° C. followed by annealing for 10 s to 120 s; maintaining the atmosphere to be pure Ar after the annealing process is completed, and taking out the wafer when the temperature is decreased to below 600° C.

2. The method according to claim 1, wherein the pressure of the reaction chamber is a normal pressure or low pressure in the range of 1 mbar to 1010 mbar.

3. The method according to claim 1, wherein the heating rate is 30° C/s to 100° C/s.

4. The method according to claim 1, wherein after the temperature is increased to a range of 1150° C. to 1300° C., the mixed atmosphere of Ar+n % H₂ in the heating-up stage is maintained, or switched to a pure Ar atmosphere.

5. The method according to claim 1, wherein the cooling rate is 30° C/s to 100° C/s.
